(19) United States
(12) Patent Application Publication
(10) Pub. No.: US 2020/0273986 A1
(43) Pub. Date: Aug. 27, 2020

(54) VERTICAL POWER TRANSISTOR WITH HIGH CONDUCTIVITY AND HIGH BLOCKING BEHAVIOR

(71) Applicant: Robert Bosch GmbH, Stuttgart (DE)

(72) Inventors: Holger Bartolf, Gomaringen (DE); Wolfgang Feiler, Reutlingen (DE); Stephan Schwaiger, Nehren (DE); Jan-Hendrik Alsmeier, Pfullingen (DE); Matthias Neubauer, Reutlingen-Degerschlacht (DE)

(21) Appl. No.: 16/640,592

(22) PCT Filed: Aug. 21, 2018
(86) PCT No.: PCT/EP2018/072474

§ 371 Date: Apr. 6, 2020

(30) Foreign Application Priority Data
Aug. 29, 2017 (DE) 10 2017 215 029.7

(51) Int. Cl. H01L 29/78; H01L 29/16; H01L 29/06; H01L 29/10; H01L 21/04; H01L 29/66

(52) U.S. Cl. CPC H01L 29/7813; H01L 29/1608; H01L 29/063; H01L 29/66068; H01L 29/1095; H01L 21/0465; H01L 21/0475; H01L 29/0661

(57) ABSTRACT

A vertical power transistor including a semiconductor substrate, which has a front side on which at least one epitaxial layer, one channel layer, and one source layer are situated. The epitaxial layer includes a first semiconductor material which has a first doping, and a plurality of first trenches and second trenches, the first trenches and the second trenches being situated alternatingly and extending perpendicularly at least into the channel layer starting from a surface of the source layer, an area extending perpendicularly into the epitaxial layer, starting from an underside of each first trench bottom, the area including a second semiconductor material which encompasses a second doping.

### FIELD

The present invention relates to a vertical power transistor with high conductivity and high blocking behavior and to a method for manufacturing such a vertical power transistor.

### BACKGROUND INFORMATION

In the case of vertical power transistors, the shielding of the gate oxide from high field strengths at a high drain source voltage is problematic in blocking operation. In order to ensure the shielding of the gate oxide, deep-reaching p+ doped areas are generated, for example, by high-energy ion implantation at the side of the MOS head.

The disadvantage here is that severe damage to the semiconductor crystal is generated by the lateral ion scattering of the deep implantation. In addition, high-energy ion implantation is very expensive.

An object of the present invention is to minimize damage to the semiconductor crystal.

### SUMMARY

A vertical power transistor in according with an example embodiment of the present invention includes a semiconductor substrate, on the front side of which at least one epitaxial layer, one channel layer, and one source layer are situated. The epitaxial layer includes a first semiconductor material which has a first doping. The vertical power transistor includes a plurality of first trenches and second trenches, which are arranged alternatingly. In other words, the vertical power transistor has a trench structure, which includes two different types of trenches, namely first trenches and second trenches, the different types of trenches being arranged alternatingly in the trench structure. The first trenches and the second trenches extend perpendicularly from a surface of the source layer at least into the channel layer. According to the present invention, an area extends perpendicularly into the epitaxial layer, starting from an underside of each first trench bottom, the area including a second semiconductor material which encompasses a second doping.

An advantage here is that the lateral scattering of the doping ions in the area underneath the first trenches is low in order to achieve a high integration density.

In one refinement of the present invention, the first trenches include a lesser depth than the second trenches. In other words, the first trenches are flatter than the second trenches.

An advantage here is that the scattering of the ions, which dope the area underneath the first trenches, is low.

In one further embodiment of the present invention, the first trenches each include a first section and a second section, the first section being situated on the second section and the second section extending from a trench bottom up to the first section, the second section including a lesser width than the first section.

An advantage here is that the dimensions of the area underneath the first trenches may be more precisely defined, i.e., the pitch dimension is small and the integration density is high.

In one refinement of the present invention, the side walls of the first section include the second semiconductor material, which has the second doping.

An advantage here is that the maximum field strengths are localized deep in the semiconductor in the blocking state of the component. The field strengths are thus heavily reduced in the gate oxide so that the service life of the component is significantly increased.

In one refinement of the present invention, the first doping is an n-doping and the second doping is a p-doping.

An example method according to the present invention for manufacturing a vertical power transistor having a semiconductor substrate, on the front side of which at least one epitaxial layer, one channel layer, and one source layer are situated, includes the generation of a first mask on the source layer, which functions as etch masking and implantation masking, and the generation of a plurality of first sections of first trenches, which have a first depth, the first sections of the first trenches extending into the interior of the epitaxial layer starting from a surface of the source layer. Furthermore, the method includes the implantation of areas, which extend perpendicularly from an underside of each first trench bottom into the epitaxial layer, the areas having a second doping, and the removal of the first mask.

An advantage here is that the area underneath the first trenches is more compact, i.e., the lateral scattering of the ions is substantially lower than in the case of a deep implantation process. A further advantage is that manufacturing costs are saved due to the lower implantation energy.

In one refinement of the present invention, the method includes the generation of a second mask, which reduces the diameter of the first sections of the first trenches and functions as etch masking, the generation of second sections of first trenches, which have a second depth, and the removal of the second mask.

Additional advantages arise from the description below of exemplary embodiments and from the figures.

### BRIEF DESCRIPTION OF THE DRAWINGS

The present invention is described in greater detail below by way of preferred specific embodiments and the figures.

FIG. 1 shows a detail of a vertical power transistor from the related art.

FIG. 2 shows a detail of a vertical power transistor according to the present invention including implanted areas underneath the first trenches.

FIG. 3 shows a detail of a further vertical power transistor according to the present invention including implanted areas underneath the first trenches.

FIG. 4 shows a method according to the present invention for manufacturing a vertical power transistor including implanted areas underneath the first trenches.

FIG. 5 shows a further method according to the present invention for manufacturing a vertical power transistor including implanted areas underneath the first trenches.

### DETAILED DESCRIPTION OF EXAMPLE EMBODIMENTS

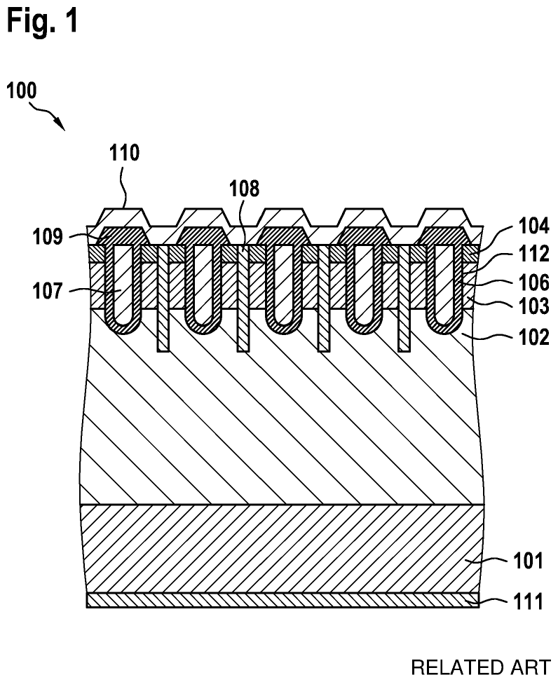

FIG. 1 shows a detail of a vertical power transistor 100 from the related art. Vertical power transistor 100 includes a semiconductor substrate 101, on the front side of which an epitaxial layer 102 is situated. Epitaxial layer 102 includes a first semiconductor material, which is doped with first charge carriers, for example, n-doped SiC. Ions, for example, made from Al, are implanted in the upper area of epitaxial layer 102, so that a p-doping is generated in the upper area of the epitaxial layer. A channel layer 103, which functions as a channel area, is thus formed in the upper area of epitaxial layer 102. A further semiconductor layer, which includes the n+ doped source area 104, is situated on channel layer 103. Vertical power transistor 100 includes a trench structure, i.e., a plurality or a multitude of trenches. A gate dielectric 106 and a gate electrode 107 are situated in each trench 112. A structured insulation layer 109, which electrically insulates gate electrode 107 from source area 104, is situated on each trench 112, i.e., above the trench structure. Deep-reaching p+ areas 108 are situated at the sides between trenches 112. In other words, deep-reaching p+ areas 108 are situated in a structured way at the side of the MOS head. P+ areas 108 have a greater depth than trenches 112, i.e., they are kept lower than the MOS head and shield the MOS head from high field strengths. A metal layer 110 is situated on structured insulation layer 109. A drain metallization 111 is situated on the rear side of semiconductor substrate 101.

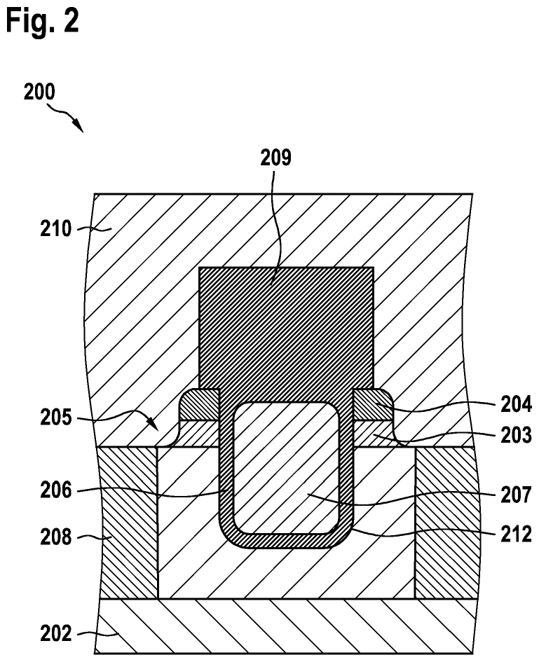

FIG. 2 shows a detail of a vertical power transistor 200 in accordance with an example embodiment of the present invention. The vertical power transistor 200 includes an epitaxial layer 202, a channel layer 203, and a source layer 204. Vertical power transistor 200 includes a plurality of first trenches 205 and second trenches 212. First trenches 205 and second trenches 212 are situated alternatingly, i.e., a second trench is situated at the side next to a first trench, a further first trench being situated next to the second trench, etc. Second trenches 212 are filled with a gate dielectric 206 and a gate electrode 207. A structured insulation layer 209 is situated on second trenches 212. First trenches 205 extend at least up to channel layer 203. An area 208, which is, for example, p+ doped, is situated underneath first trenches 205. Area 208 thereby extends into epitaxial layer 202, starting from the trench bottom of each first trench 205. First trenches 205 are filled with metal 210.

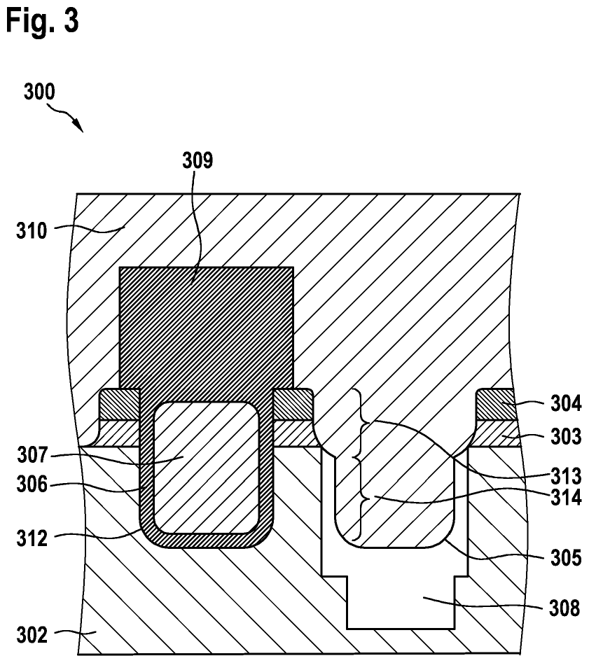

FIG. 3 shows a detail of a further vertical power transistor 300 in accordance with an example embodiment of the present invention. The further vertical power transistor 300 includes an epitaxial layer 302, a channel layer 303, and a source layer 304. Vertical power transistor 300 includes a plurality of first trenches 305 and second trenches 312. First trenches 305 include a first section 313 and a second section 314. Second section 314 thereby extends from the trench bottom up to first section 313. In other words, the first trenches are designed to have two stages, the first trenches including a narrow, deep section and a broad, flat section. First trenches 305 and second trenches 312 are situated alternatingly, i.e., a second trench is situated at the side next to a first trench, a further first trench being situated next to the second trench, etc. Second trenches 312 are filled with a gate dielectric 306 and a gate electrode 307. A structured insulation layer 309 is situated on second trenches 312. First trenches 305 extend at least up to channel layer 303 or into epitaxial layer 302. An area 308, which is, for example, p+ doped, is situated underneath first trenches 305. Area 308 thereby extends perpendicular into epitaxial layer 302. Furthermore, the side walls of the first sections are p-doped. In other words, the p-doped areas are located in the semiconductor material, which is adjacent to the side walls and the bottom of second sections 314 of first trenches 305. First trenches 305 are filled with metal 310.

These vertical power transistors may be used in vehicle inverters, for example, in electric or hybrid vehicles. In addition, they may be used in photovoltaic or wind power inverters, traction drives, or high voltage rectifiers.

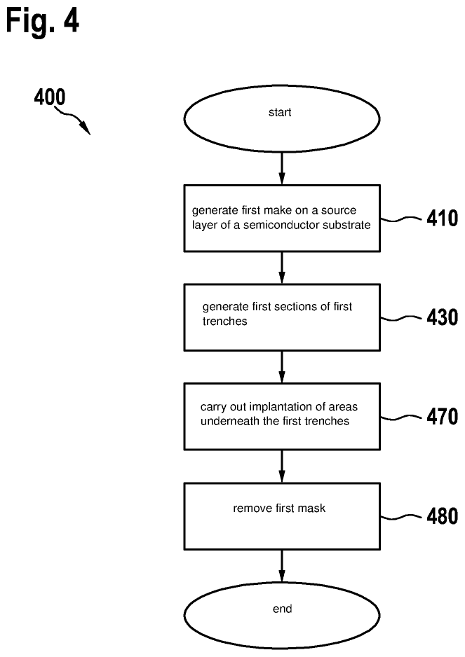

FIG. 4 shows an example method in accordance with an example embodiment of the present invention for manufacturing a vertical power transistor including implanted areas underneath the first trenches. The method starts with a step 410, in which a first mask is generated on a source layer of a semiconductor substrate. The source layer is thereby the topmost layer of a layer sequence made up of an epitaxial layer, a channel layer, and a source layer, which are situated on the semiconductor substrate. The first mask includes, for example, SiO₂, poly-Si, or lacquer. In a subsequent step 430, first sections of first trenches are generated with the aid of dry etching. The depth of the first sections is thereby selected in such a way that they reach at least up to the channel layer. In other words, the dry etching step penetrates the source area. In a following step 470, the implantation of areas underneath the first trenches is carried out. The implantation is carried out using ions, so that deep-lying p+ areas are generated at the side of the MOS heads for shielding high field strengths in the blocking operation. The first mask is removed in a following step 480.

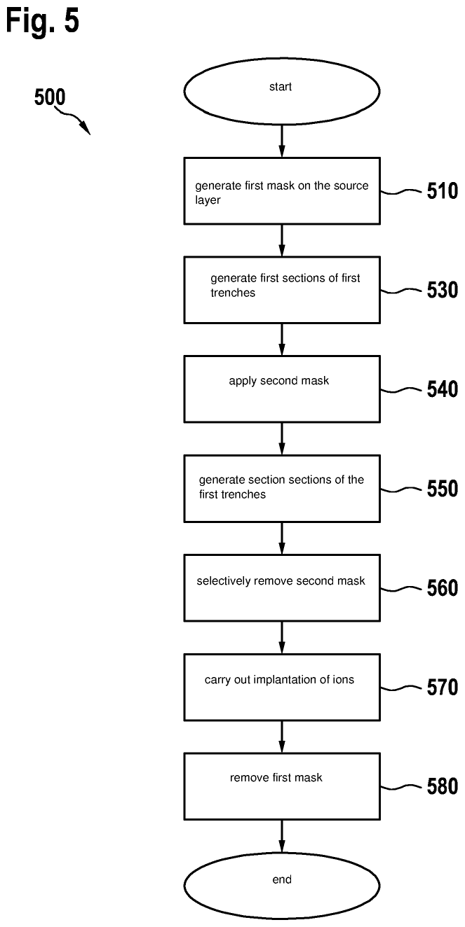

FIG. 5 shows a further method in accordance with an example embodiment of the present invention for manufacturing a vertical power transistor including implanted areas underneath the first trenches. The method starts with a step 510, in which a first mask is generated on the source layer. In a following step 530, the first sections of the first trenches are generated with the aid of dry etching. The depth of the first sections is thereby selected in such a way that the first sections reach into the channel layer. In other words, the broad, flat section of the first trenches is generated using this step. In a following step 540, a second mask is applied, the second mask having a determined thickness so that the opening of the implantation mask is reduced by twice the determined thickness. In a following step 550, the second sections of the first trenches are generated with the aid of dry etching. In other words, the narrow, deep section of the first trenches is generated in this step. The second section is thus situated axially symmetrical to the first sections, i.e., flush, and has a width that is smaller than that of the first section by twice the determined thickness. In a following step 560, the second mask is selectively removed. In a following step 570, the implantation with ions is carried out. Areas with the second doping for shielding from high field strengths are thus generated both on the side walls of the second sections and also underneath the first trenches. The implantation is carried out, for example, with the aid of a cascading implantation step, so that the highest implantation energy is used initially, and the implantation energy is subsequently successively reduced. It is thereby important that a good ohmic contact is generated between the areas with the second doping and the metallization. Retrograde profiles may also be generated in which the Al concentration initially increases in the direction of the drain, and then drops again. The first mask is removed in a following step 580.

In a second exemplary embodiment, the first trenches are generated chronologically after the second trenches.

1-7. (canceled)

8. A vertical power transistor, comprising:
a semiconductor substrate which has a front side on which at least one epitaxial layer, at least one channel layer, and at least one source layer are situated, the epitaxial layer including a first semiconductor material which has a first doping, and a plurality of first trenches and second trenches, the first trenches and the second trenches are situated alternatingly relative to one another and extend perpendicularly at least into the channel layer, starting from a surface of the source layer;
wherein an area extends perpendicularly into the epitaxial layer, starting from an underside of each first trench bottom, the area including a second semiconductor material which has a second doping.

9. The vertical power transistor as recited in claim 8, wherein the first trenches have a lesser depth than the second trenches.

10. The vertical power transistor as recited in claim 8, wherein each of the first trenches has a first section and a second section, the first section being situated on the second section and the second section extending from a trench bottom up to the first section, and the second section has a lesser width than the first section.

11. The vertical power transistor as recited in claim 10, wherein side walls of the second section include the second semiconductor material which has the second doping.

12. The vertical power transistor as recited in claim 8, wherein the first doping is an n-doping and the second doping is a p-doping.

13. A method for manufacturing a vertical power transistor including a semiconductor substrate, which has a front side on which at least one epitaxial layer, at least one channel layer, and at least one source layer are situated, the method comprising the following steps:
generating a first mask on the source layer which functions as an etch masking and an implantation masking;
generating a plurality of first sections of first trenches, which have a first depth, the first sections of the first trenches extending into an interior of the epitaxial layer, starting from a surface of the source layer;
implanting areas which extend perpendicularly from an underside of each first trench bottom into the epitaxial layer, the areas having a second doping; and
removing the first mask.

14. The method as recited in claim 13, further comprising the following steps:
generating a second mask which reduces a diameter of the first sections of the first trenches and functions as an etch masking;
generating second sections of the first trenches which have a second depth; and
removing the second mask.
